(19) United States
(12) Patent Application Publication
(10) Pub. No.: US 2024/0315050 A1
(43) Pub. Date: Sep. 19, 2024

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Hui-Lin Wang, Taipei City (TW); Che-Wei Chang, Taichung City (TW); Ching-Hua Hsu, Kaohsiung City (TW); Chen-Yi Weng, New Taipei City (TW)

(73) Assignee: UNITED MICROELECTRONICS CORP., Hsin-Chu City (TW)

(21) Appl. No.: 18/676,441

(22) Filed: May 28, 2024

(30) Foreign Application Priority Data
Apr. 18, 2024 (TW) 113114457

(51) Int. Cl. H10B 61/00; G01R 33/09; H10N 50/01; H10N 50/10; H10N 50/20

(52) U.S. Cl. CPC H10B 61/22; G01R 33/098; H10N 50/01; H10N 50/10; H10N 50/20

(57) ABSTRACT

A method for fabricating a semiconductor device includes the steps of first forming an inter-metal dielectric (IMD) layer on a substrate, forming a first trench in the IMD layer, forming a metal layer in the first trench, planarizing the metal layer to form a first metal interconnection in the IMD layer and a first recess atop the first metal interconnection, and then forming a first bottom electrode (BE) in the first recess.

### BACKGROUND OF THE INVENTION

### 1. Field of the Invention

The invention relates to a semiconductor device and method for fabricating the same, and more particularly to a magnetoresistive random access memory (MRAM) and method for fabricating the same.

### 2. Description of the Prior Art

Magnetoresistance (MR) effect has been known as a kind of effect caused by altering the resistance of a material through variation of outside magnetic field. The physical definition of such effect is defined as a variation in resistance obtained by dividing a difference in resistance under no magnetic interference by the original resistance. Currently, MR effect has been successfully utilized in production of hard disks thereby having important commercial values. Moreover, the characterization of utilizing GMR materials to generate different resistance under different magnetized states could also be used to fabricate MRAM devices, which typically has the advantage of keeping stored data even when the device is not connected to an electrical source.

The aforementioned MR effect has also been used in magnetic field sensor areas including but not limited to for example electronic compass components used in global positioning system (GPS) of cellular phones for providing information regarding moving location to users. Currently, various magnetic field sensor technologies such as anisotropic magnetoresistance (AMR) sensors, GMR sensors, magnetic tunneling junction (MTJ) sensors have been widely developed in the market. Nevertheless, most of these products still pose numerous shortcomings such as high chip area, high cost, high power consumption, limited sensibility, and easily affected by temperature variation and how to come up with an improved device to resolve these issues has become an important task in this field.

### SUMMARY OF THE INVENTION

According to an embodiment of the present invention, a method for fabricating a semiconductor device includes the steps of first forming an inter-metal dielectric (IMD) layer on a substrate, forming a first trench in the IMD layer, forming a metal layer in the first trench, planarizing the metal layer to form a first metal interconnection in the IMD layer and a first recess atop the first metal interconnection, and then forming a first bottom electrode (BE) in the first recess.

According to another aspect of the present invention, a semiconductor device includes an inter-metal dielectric (IMD) layer on a substrate, a first trench in the IMD layer, a first metal interconnection in the first trench, a first bottom electrode (BE) on the first metal interconnection, a spin orbit torque (SOT) layer on the first BE, and a magnetic tunneling junction (MTJ) on the SOT layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate a method for fabricating a MRAM device according to an embodiment of the present invention.

FIG. 9 illustrates a structural view of a MRAM device according to an embodiment of the present invention.

### DETAILED DESCRIPTION

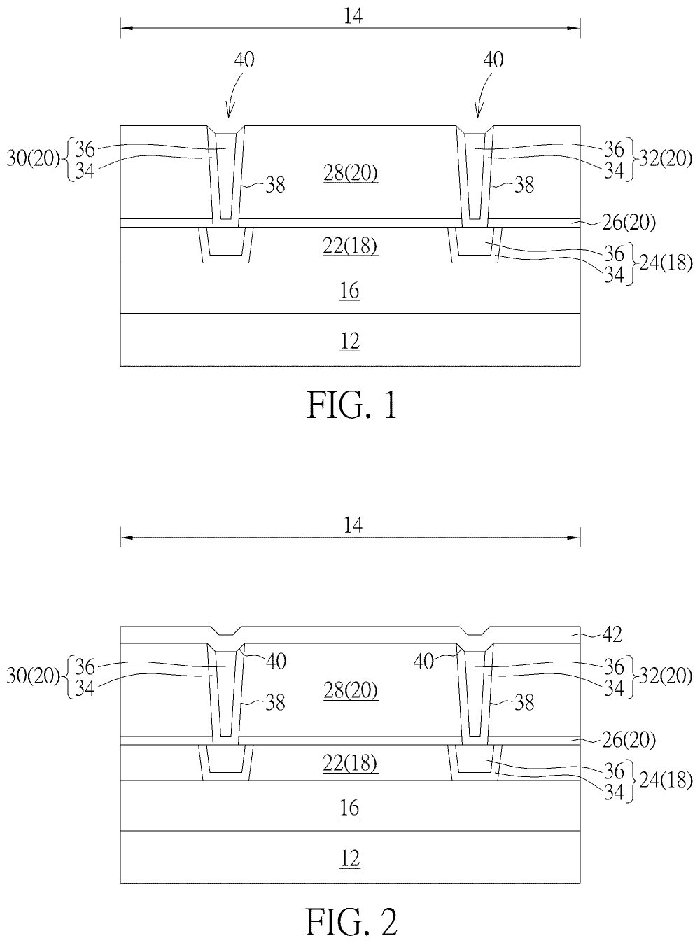

Referring to FIGS. 1-8, FIGS. 1-8 illustrate a method for fabricating a semiconductor device, or more specifically a MRAM device according to an embodiment of the present invention. As shown in FIG. 1, a substrate 12 made of semiconductor material is first provided, in which the semiconductor material could be selected from the group consisting of silicon (Si), germanium (Ge), Si—Ge compounds, silicon carbide (SiC), and gallium arsenide (GaAs), and a MRAM region 14 and a logic region (not shown) are defined on the substrate 12.

Active devices such as metal-oxide semiconductor (MOS) transistors, passive devices, conductive layers, and interlayer dielectric (ILD) layer 16 could also be formed on top of the substrate 12. More specifically, planar MOS transistors or non-planar (such as FinFETs) MOS transistors could be formed on the substrate 12, in which the MOS transistors could include transistor elements such as gate structures (for example metal gates) and source/drain region, spacer, epitaxial layer, and contact etch stop layer (CESL). The ILD layer 16 could be formed on the substrate 12 to cover the MOS transistors, and a plurality of contact plugs could be formed in the ILD layer 16 to electrically connect to the gate structure and/or source/drain region of MOS transistors. Since the fabrication of planar or non-planar transistors and ILD layer is well known to those skilled in the art, the details of which are not explained herein for the sake of brevity.

Next, metal interconnect structures 18, 20 are sequentially formed on the ILD layer 16 to electrically connect the aforementioned contact plugs, in which the metal interconnect structure 18 includes an inter-metal dielectric (IMD) layer 22 and metal interconnections 24 embedded in the IMD layer 22, and the metal interconnect structure 20 includes a stop layer 26, an IMD layer 28, and metal interconnections 30, 32 embedded in the stop layer 26 and the IMD layer 28.

In this embodiment, each of the metal interconnections 24 from the metal interconnect structure 18 preferably includes a trench conductor and each of the metal interconnections 30, 32 from the metal interconnect structure 20 includes a via conductor. Preferably, each of the metal interconnections 24, 30, 32 from the metal interconnect structures 18, 20 could be embedded within the IMD layers 22, 28 and/or stop layer 26 according to a single damascene process or dual damascene process. For instance, each of the metal interconnections 24, 30, 32 could further include a barrier layer 34 and a metal layer 36, in which the barrier layer 34 could be selected from the group consisting of titanium (Ti), titanium nitride (TiN), tantalum (Ta), and tantalum nitride (TaN) and the metal layer 36 could be selected from the group consisting of tungsten (W), copper (Cu), aluminum (Al), titanium aluminide (TiAl), and cobalt tungsten phosphide (CoWP). Since single damascene process and dual damascene process are well known to those skilled in the art, the details of which are not explained herein for the sake of brevity. In this embodiment, the metal layers 36 in the metal interconnections 24 are preferably made of copper, the metal layers 36 in the metal interconnections 30, 32 are preferably made of tungsten, the IMD layers 22, 28 are preferably made of silicon oxide or ultra low-k (ULK) dielectric layer, and the stop layers 26 is preferably made of nitrogen doped carbide (NDC), silicon nitride, silicon carbon nitride (SiCN), or combination thereof.

It should be noted that as shown in FIG. 1, during the formation of the metal interconnections 30, 32 in the IMD layer 28, a photo-etching process is first conducted to remove part of the IMD layer 28 and part of the stop layer 26 for forming openings or trenches 38 exposing surface of the metal interconnections 24 underneath, and then a barrier layer 34 and a metal layer 36 are formed in the trenches 38. Preferably, the barrier layer is deposited on the surface of the IMD layer 28 and bottom surface and sidewalls of the trenches while the metal layer 36 is formed on the barrier layer 34 and filling the trenches 38 completely.

Next, a planarizing process such as a chemical mechanical polishing (CMP) process is conducted to remove part of the metal layer 36 and part of the barrier layer for forming two metal interconnections 30, 32 in the IMD layer 28. It should be noted that the CMP process conducted at this stage not only removes all of the metal layer 36 and barrier layer 34 on top surface of the IMD layer 28 but also removes a little bit more of the metal layer 36 and part of the barrier layer 34 in the trenches 38 so that the top surface of the remaining metal layer 36 and barrier layer 34 is slightly lower than the top surface of the IMD layer 28. This forms metal interconnections 30, 32 and at the same time forms smaller recesses 40 directly on top of the metal interconnections 30, 32. According to an embodiment of the present invention, the depth of each recess or the distance measuring from the top surface of the metal interconnections 30, 32 to the top surface of the IMD layer 28 is approximately 60-80 Angstroms or most preferably 70 Angstroms.

Next, as shown in FIG. 2, a bottom electrode (BE) layer 42 is formed on the IMD layer 28 to fill the recesses 40. In this embodiment, the BE layer 42 preferably includes metal or metal nitride such as but not limited to for example tantalum (Ta) or tantalum nitride (TaN).

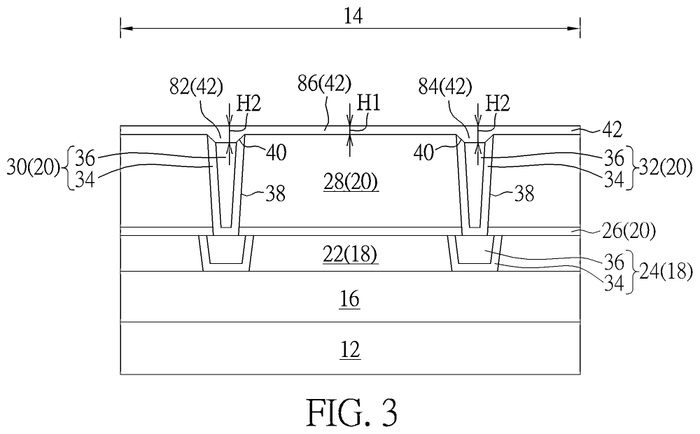

Next, as shown in FIG. 3, another planarizing process such as CMP process is conducted to remove part of the BE layer 42 so that the thickness of the BE layer 42 is slightly reduced but still covering the entire top surface of the IMD layer 28 while filling the recesses 40 entirely. In this embodiment, the BE layer 42 after the planarizing process could include BE 82 disposed in the left recess 40, BE 84 disposed in the right recess 40, and BE 86 disposed on the surface of the IMD layer 28 between the two metal interconnections 30, 32. Preferably, the height H1 of the BE 86 disposed on the surface of the IMD layer 28 is between 0-30 Angstroms and the height H2 including the height of the BE 82 in the left recess 40 plus the height H1 of the BE 86 directly atop of BE 82 or the height of the BE 84 in the right recess 40 and the height H1 of the BE 86 directly atop of BE 84 is between 30-100 Angstroms.

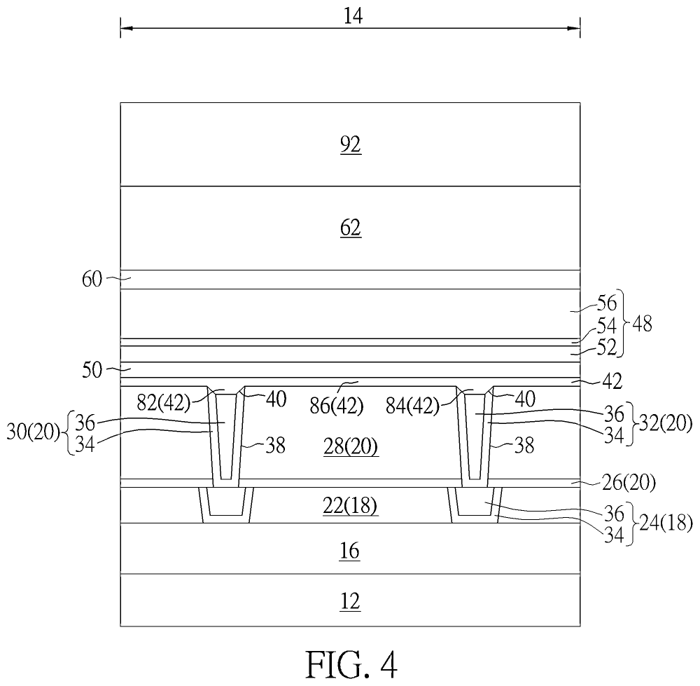

Next, as shown in FIG. 4, a spin orbit torque (SOT) layer 50 is formed on the surface of the BE layer 42, a MTJ stack 48 is formed on the SOT layer 50, and then a cap layer 60 and a composite hard mask such as a hard mask 62 and hard mask 92 are formed on the MTJ stack 48.

In this embodiment, the formation of the MTJ stack 48 could be accomplished by sequentially depositing a free layer 52, a barrier layer 54, and a pinned layer 56 on the SOT layer 50. Preferably, the free layer 52 could be made of ferromagnetic material including but not limited to for example iron, cobalt, nickel, or alloys thereof such as cobalt-iron-boron (CoFeB), in which the magnetized direction of the free layer 52 could be altered freely depending on the influence of outside magnetic field. The barrier layer 54 could be made of insulating material including but not limited to for example oxides such as aluminum oxide (AlOₓ) or magnesium oxide (MgO). The pinned layer 56 could be made of antiferromagnetic (AFM) material including but not limited to for example ferromanganese (FeMn), platinum manganese (PtMn), iridium manganese (IrMn), nickel oxide (NiO), or combination thereof, in which the pinned layer 56 is formed to fix or limit the direction of magnetic moment of adjacent layers. It should be noted that since the present embodiment pertains to fabricating a SOT MRAM device, the free layer 52 is preferably disposed on the bottommost layer to contact the SOT layer 50 directly.

Preferably, the SOT layer 50 is serving as a channel for the MRAM device as the SOT layer 50 could include metals such as tantalum (Ta), tungsten (W), platinum (Pt), or hafnium (Hf) and/or topological insulator such as bismuth selenide (BiₓSe₁₋ₓ). The cap layer 60 preferably includes metal such as Ta and the hard mask 62 preferably includes conductive material such as metal or metal nitride, in which metal could include Ti whereas metal nitride could include TiN. Nevertheless, the cap layer 60 or hard mask 62 could all include conductive or dielectric material including but not limited to for example Ta, TaN, Ti, TIN, Pt, Cu, Au, Al, or combination thereof. The hard mask 92 could include dielectric material such as silicon oxide, but not limited thereto.

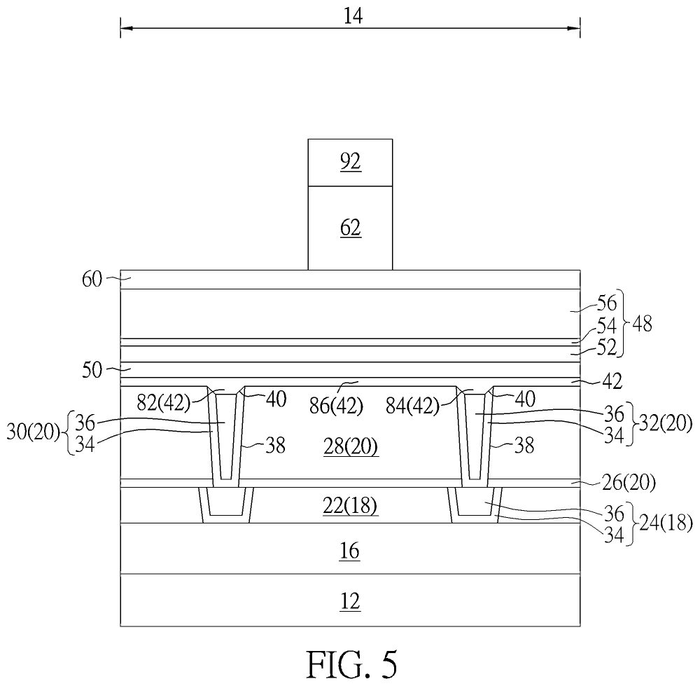

Next, as shown in FIG. 5, an etching process is conducted by using a patterned mask such as patterned resist (not shown) as mask to remove part of the hard mask 92 and part of the hard mask 62 for forming patterned mask 92 and patterned hard mask 62.

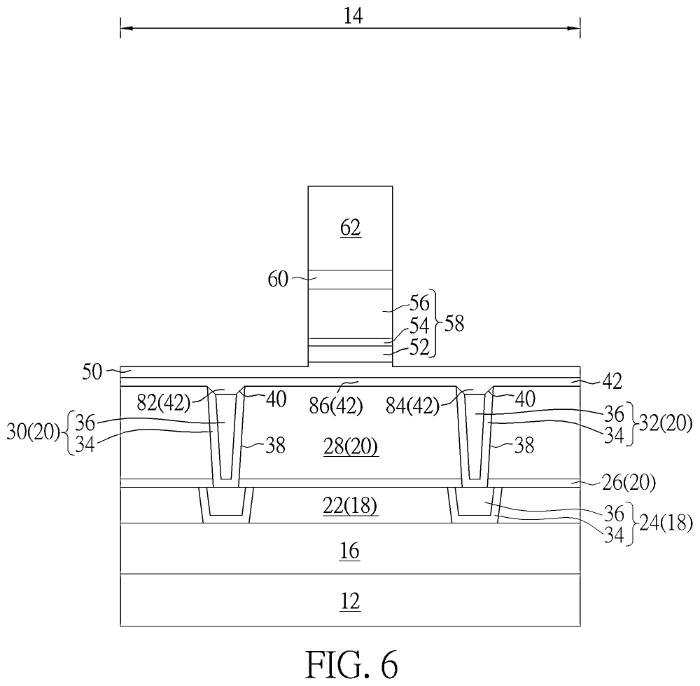

Next, as shown in FIG. 6, after removing the patterned hard mask 92, one or more etching process is conducted by using the patterned hard mask 62 as mask to remove part of the MTJ stack 48 and even part of the SOT layer 50 for forming a MTJ 58 on the SOT layer 50.

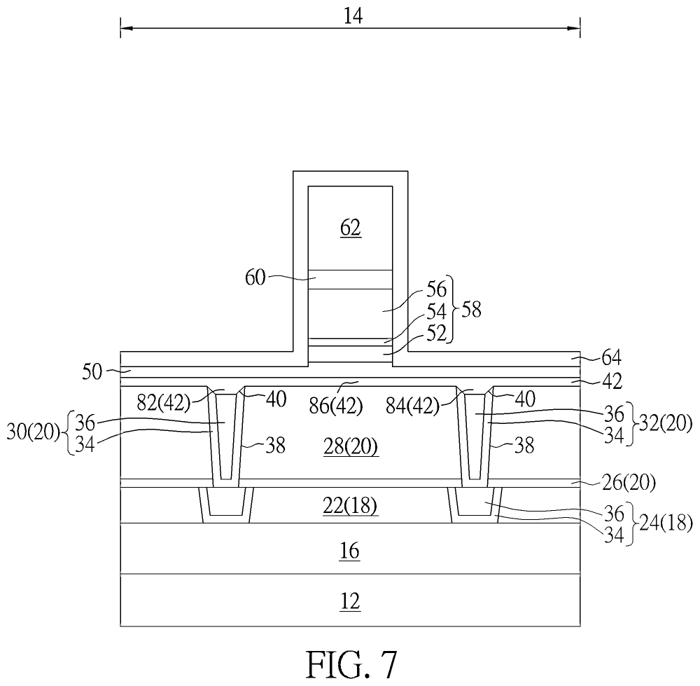

Next, as shown in FIG. 7, a cap layer 64 is formed on the surface of the hard mask 62, MTJ 58, and SOT layer 50. In this embodiment, the SOT layer 50 could be etched or not etched during the patterning of the MTJ stack 48 so that after the MTJ 58 is formed, the top surface of the SOT layer 50 directly under the MTJ 58 could be even with or slightly higher than the top surface of the SOT layer 50 adjacent two sides of the MTJ 58, which are all within the scope of the present invention. Preferably, the cap layer 64 is made of nitrogen doped carbide (NDC), silicon nitride (SiN), silicon carbon nitride (SiCN), or combination thereof and most preferably made of SiN.

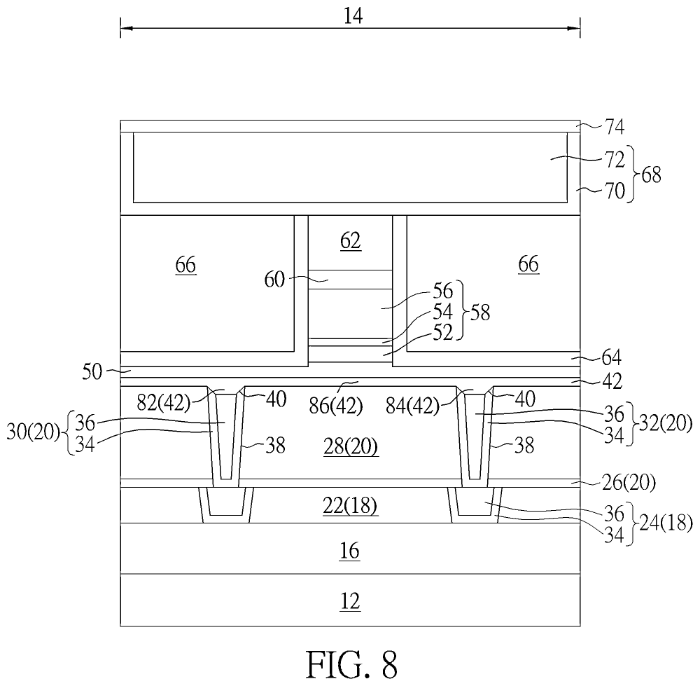

Next, as shown in FIG. 8, an IMD layer 66 is formed on the cap layer 60 and one or more photo-etching process is conducted to remove part of the IMD layer 66 and part of the cap layer 60 to form at least a contact hole (not shown) exposing the hard mask 62. Next, conductive materials are deposited into the contact hole and planarizing process such as CMP is conducted to form metal interconnection 68 connecting the hard mask 62 underneath, and another stop layer 74 is formed on the surface of the metal interconnection 68 thereafter. Similar to the aforementioned metal interconnections 24, the metal interconnection 68 could be embedded within the IMD layer 66 according to a single damascene process or dual damascene process. For instance, the metal interconnection 68 could further include a barrier layer 70 and a metal layer 72, in which the barrier layer 70 could be selected from the group consisting of titanium (Ti), titanium nitride (TiN), tantalum (Ta), and tantalum nitride (TaN) and the metal layer 72 could be selected from the group consisting of tungsten (W), copper (Cu), aluminum (Al), titanium aluminide (TiAl), and cobalt tungsten phosphide (CoWP).

In this embodiment, the IMD layer 66 preferably include an ultra low-k (ULK) dielectric layer including but not limited to for example porous material or silicon oxycarbide (SiOC) and the stop layer 74 preferably includes nitrogen doped carbide (NDC), silicon nitride (SIN), silicon carbon nitride (SiCN), or combination thereof and most preferably includes SiN. This completes the fabrication of a semiconductor device according to an embodiment of the present invention.

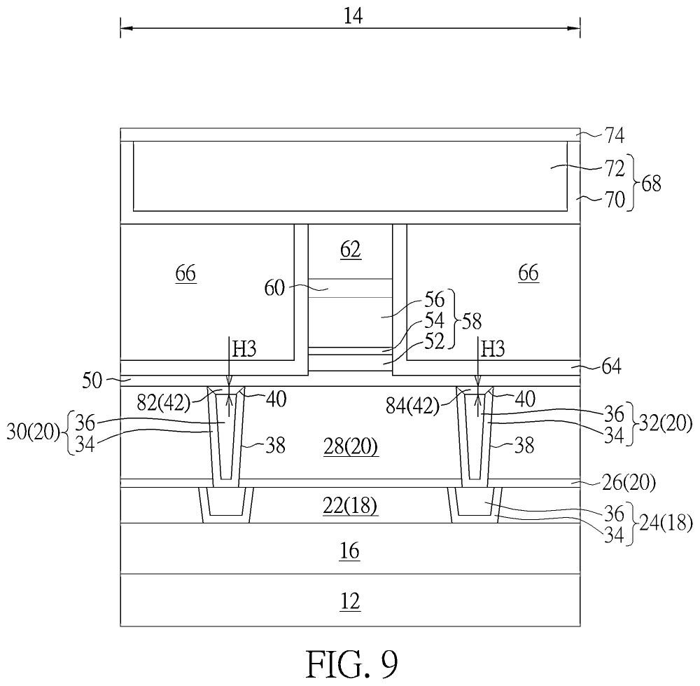

Referring to FIG. 9, FIG. 9 further illustrates a structural view of a MRAM device according to an embodiment of the present invention. As shown in FIG. 9, the MRAM device includes an IMD layer 28 disposed on the substrate 12, two openings or trenches 38 disposed in the IMD layer 28, metal interconnections 30, 32 disposed in the trenches 38, a SOT layer 50 disposed on the metal interconnections 30, 32, and a MTJ 58 disposed on the SOT layer 50.

In contrast to disposing a BE 86 between the IMD layer 28 and the SOT layer 50 in the aforementioned embodiment, the present embodiment could conduct the CMP process in FIG. 3 to completely remove all the BE layer 42 on the IMD layer 28 surface and expose the surface of the IMD layer 28 so that the SOT layer 50 could directly contact the IMD layer 28 underneath as the remaining BE layer 42 is only disposed in the recesses 40 directly atop the metal interconnections 30, 32 for forming the BE 82 and BE 84. Since the top surface of the BE 82 and BE 84 is even with the surface of the IMD layer 28, the height H3 of the BE 82 and BE 84 is slightly lower than the height H2 from previous embodiment. For instance, the height H3 is preferably between 30-70 Angstroms. It should be noted that even though each of the BEs 82, 84 have a substantially trapezoid cross-section while having two inclined sidewalls in this embodiment, according to other embodiment of the present invention, the shape of each of the BE 82 and BE 84 could all be adjusted according to the shape of the recesses 40. For instance, rectangular recesses 40 having vertical sidewalls could be formed directly above the metal interconnections 30, 32 from FIG. 1 so that each of the BE 82 and BE 84 formed in the recesses 40 afterwards would also have rectangular cross-section with vertical sidewalls, which is also within the scope of the present invention.

Overall, the present invention discloses a SOT MRAM structure and fabrication method thereof, which first forms two trenches 38 in the IMD layer, deposits conductive material into the trenches for forming metal interconnections 30, 32 while having the top surface of the metal interconnections 30, 32 to be slightly lower than the top surface of the IMD layer on adjacent sides for forming recesses 40 atop the metal interconnections, forms a BE layer 42 on the metal interconnections to fill the recesses, and then form a STO layer and MTJ on the BE layer thereafter. Preferably, the BE layer 42 could be disposed directly above the metal interconnections 30, 32 and on the surface of the IMD layer between the two metal interconnections 30, 32 as shown in FIG. 8 or could only be disposed directly above the metal interconnections 30, 32 as shown in FIG. 9. By adjusting the height H1 of the BE layer 42 to be greater than 0 as shown in FIG. 8 or adjusting the height H1 of the BE layer 42 to be 0 as shown in FIG. 9, the present invention could lower shunting path of the BE layer by reducing its thickness thereby further reducing resistance of the BE and increasing read and write efficiency between SOT layer and MTJ.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming an inter-metal dielectric (IMD) layer on a substrate;
forming a first trench in the IMD layer;
forming a metal layer in the first trench;
planarizing the metal layer to form a first metal interconnection in the IMD layer and a first recess atop the first metal interconnection; and
forming a first bottom electrode (BE) in the first recess.

2. The method of claim 1, further comprising:
forming the first trench and a second trench in the IMD layer;
forming the metal layer in the first trench and the second trench;
planarizing the metal layer to form the first metal interconnection, a second metal interconnection, a first recess atop the first metal interconnection, and a second recess atop the second metal interconnection;
forming the first BE in the first recess and a second BE in the second recess;
forming a spin orbit torque (SOT) layer on the first BE and the second BE; and
forming a magnetic tunneling junction (MTJ) on the SOT layer.

3. The method of claim 2, further comprising:
forming a bottom electrode (BE) layer in the first recess and the second recess;
planarizing the BE layer to form the first BE and the second BE.

4. The method of claim 3, further comprising planarizing the BE layer to form the first BE, the second BE, and a third BE on the first BE and the second BE.

5. The method of claim 4, wherein a top surface of the third BE is higher than a top surface of the IMD layer.

6. The method of claim 3, further comprising planarizing the BE layer to expose a top surface of the IMD layer.

7. A semiconductor device, comprising:
an inter-metal dielectric (IMD) layer on a substrate;
a first trench in the IMD layer;
a first metal interconnection in the first trench;
a first bottom electrode (BE) on the first metal interconnection;
a spin orbit torque (SOT) layer on the first BE; and
a magnetic tunneling junction (MTJ) on the SOT layer.

8. The semiconductor device of claim 7, further comprising:
a second trench in the IMD layer;
a second metal interconnection in the second trench; and
a second BE on the second metal interconnection.

9. The semiconductor device of claim 7, wherein top surfaces of the first BE and the IMD layer are coplanar.

10. The semiconductor device of claim 8, wherein top surfaces of the second BE and the IMD layer are coplanar.

11. The semiconductor device of claim 8, further comprising a third BE on the first BE and the second BE.

12. The semiconductor device of claim 11, wherein a top surface of the third BE is higher than a top surface of the IMD layer.
